(19) United States
(12) Patent Application Publication
(10) Pub. No.: US 2026/0184559 A1
(43) Pub. Date: Jul. 2, 2026

(54) MEMS DEVICE AND PREPARATION THEREFOR

(71) Applicant: AAC ACOUSTIC TECHNOLOGIES (SHENZHEN) CO., LTD., Shenzhen (CN)

(72) Inventors: Kaijie Wang, Shenzhen (CN); Minh Ngoc Nguyen, Bac Ninh (VN); Yu Chen, Singapore (SG)

(21) Appl. No.: 19/330,744

(22) Filed: Sep. 16, 2025

Related U.S. Application Data
(63) Continuation of application No. PCT/CN2024/143928, filed on Dec. 30, 2024.

(51) Int. Cl. B81B 3/00; B81C 1/00; G01P 15/09; H04R 7/04; H04R 7/18; H04R 17/02; H04R 31/00

(52) U.S. Cl. CPC B81B 3/0037; B81C 1/00476; G01P 15/09; B81B 2201/0235; B81B 2201/0257; B81B 2203/0127; B81C 2201/0109; B81C 2201/0133; H04R 7/04; H04R 7/18; H04R 17/02; H04R 31/003; H04R 2201/003

(57) ABSTRACT

The present application provides a MEMS device and a preparation method therefor. The MEMS device includes a piezoelectric diaphragm, a blocking layer disposed on a side of the piezoelectric diaphragm, a sacrificial layer connected to a side of the blocking layer back away from the piezoelectric diaphragm, and a substrate connected to a side of the sacrificial layer back away from the blocking layer. The substrate includes a wall connected to a side of the sacrificial layer back away from the blocking layer and forming a cavity, and a mass block disposed on the side of the sacrificial layer back away from the blocking layer and accommodated within the cavity, which is formed by etching the substrate and is spaced apart from the wall. The mass block can drive the piezoelectric diaphragm to produce significant mechanical deformation, improving the sensitivity and response efficiency of the MEMS device.

### CROSS-REFERENCE TO RELATED APPLICATIONS

This application is a continuation of International Application No. PCT/CN2024/143928, filed Dec. 30, 2024, the entire contents of which are incorporated herein by reference.

### TECHNICAL FIELD

The present application relates to the field of micro-electro-mechanical technologies, in particular to a MEMS device and a preparation therefore.

### BACKGROUND

Micro-Electro-Mechanical System (MEMS) microphones and MEMS accelerometers typically include a diaphragm and a mass block. The diaphragm is used to capture vibrations and convert mechanical vibrations into electrical signals, while the mass block is used to increase the mass of the diaphragm, causing it to vibrate more significantly.

However, the diaphragms and the mass blocks in conventional MEMS devices have several limitations. On one hand, the mass block in the conventional MEMS devices is constrained by the thickness of the deposited material, making it difficult to meet the requirements of bone conduction microphones and MEMS accelerometers. On the other hand, the diaphragms in the conventional MEMS microphones typically have low effective mass and compliance, enabling them to capture vibrations caused by sound waves in the air but struggling to effectively respond to vibrations in solid media (such as bones).

### SUMMARY

An object of the present application is to provide a MEMS device and a preparation method therefor, which can enhance the sensitivity and response capability of the MEMS device and simplify the preparation method of the MEMS device.

The technical solution of the present application is as follows:

The first aspect of the present application provides a MEMS device, including:
a piezoelectric diaphragm;
a blocking layer disposed on a side of the piezoelectric diaphragm;
a sacrificial layer connected to a side of the blocking layer back away from the piezoelectric diaphragm; and
a substrate connected to a side of the sacrificial layer back away from the blocking layer, and including:
a wall connected to a side of the sacrificial layer back away from the blocking layer, with the wall forming a cavity; and
a mass block disposed on the side of the sacrificial layer back away from the blocking layer and accommodated within the cavity, the mass block being formed by etching the substrate and being spaced apart from the wall.

As an improvement, the sacrificial layer includes a first support portion connecting the wall and the blocking layer, and a second support portion connecting the mass block and the blocking layer, with a gap between the first support portion and the second support portion.

As an improvement, the blocking layer includes a main body disposed between the piezoelectric diaphragm and the sacrificial layer, and a first blocking wall and a second blocking wall extending from the main body toward the substrate; the first blocking wall is located within the gap and covers a surface of the first support member facing the second support member, and the second blocking wall is located within the gap and covers a surface of the second support member facing the first support member.

As an improvement, the sacrificial layer and the blocking layer are made of different materials.

As an improvement, the piezoelectric diaphragm includes a fixing portion fixed to the wall and a plurality of cantilever portions extending from the fixing portion toward an upper portion of the cavity and suspending the mass block within the cavity, wherein the plurality of cantilever portions are spaced apart from each other or the plurality of cantilever portions are connected together as a single unit.

The second aspect of the present application provides a preparation method for a MEMS device, including:
preparing a substrate;
depositing a sacrificial layer on a surface of the substrate, and depositing a blocking layer on a side of the sacrificial layer back away from the substrate;
preparing a piezoelectric diaphragm on a side of the blocking layer back away from the sacrificial layer; and
etching a side of the substrate back away from the sacrificial layer to form the wall and a mass block, wherein the wall encloses a cavity, the mass block is accommodated within the cavity and spaced apart from the wall, and the sacrificial layer is exposed through a spacing between the mass block and the wall.

As an improvement, after depositing the sacrificial layer on the surface of the substrate, the method further includes:
etching the sacrificial layer to form a first channel and a second channel that are arranged through the sacrificial layer along a thickness direction, wherein the first channel and the second channel are both annular in shape, and the first channel is arranged around an outer side of the second channel;
the step of depositing the blocking layer on the side of the sacrificial layer back away from the substrate includes:
depositing polysilicon on the surface of the sacrificial layer back away from the substrate to form a main body of the blocking layer, and depositing polysilicon within the first channel and the second channel to form a first blocking wall and a second blocking wall, respectively.

As an improvement, the step of etching the side of the substrate back away from the sacrificial layer to form the wall and the mass block includes:
etching the side of the substrate back away from the sacrificial layer to form a through-hole in a region of the substrate corresponding to the first blocking wall and the second blocking wall, exposing the sacrificial layer through the through-hole, wherein the through-hole forms the spacing between the wall and the mass block.

As an improvement, after etching the side of the substrate back away from the sacrificial layer to form the wall and the mass block, the method further includes:
etching the sacrificial layer to remove the sacrificial layer exposed through the through-hole between the first blocking wall and the second blocking wall, thereby forming a gap within the sacrificial layer.

As an improvement, the step of preparing the piezoelectric diaphragm on the side of the blocking layer back away from the sacrificial layer includes:
depositing piezoelectric material on the side of the blocking layer away from the substrate to form a first piezoelectric layer;
depositing a first electrode material on a side of the first piezoelectric layer back away from the substrate and patterning it to form a first electrode;
depositing piezoelectric material on a side of the first electrode back away from the first piezoelectric layer to form a second piezoelectric layer;
depositing a first electrode material on a side of the second piezoelectric layer back away from the substrate and patterning it to form a second electrode;
depositing piezoelectric material on the side of the second electrode back away from the second piezoelectric layer to form a third piezoelectric layer; and
etching the second piezoelectric layer and/or the third piezoelectric layer to form an electrode hole, and depositing conductive material within the electrode hole to connect the first electrode and the second electrode to a surface of the third piezoelectric layer back away from the substrate.

The beneficial effects of the present application are as follows: the mass block of the MEMS device in the present application is formed by etching the substrate and is accommodated within a cavity formed by etching the substrate. This eliminates the need for additional deposition processes to fabricate the mass block on the substrate, thereby freeing its thickness from the constraints of deposition techniques and meeting the requirements of bone conduction microphones and MEMS accelerometers. After capturing and amplifying vibration signals, the mass block can drive the piezoelectric diaphragm to produce significant mechanical deformation, effectively detecting vibrations in solid media, and enhancing the sensitivity and response efficiency of the MEMS device.

### BRIEF DESCRIPTION OF THE DRAWINGS

FIG. 1 is a schematic diagram of an overall structure of a MEMS device according to an embodiment of the present application.

FIG. 2 is a cross-sectional schematic diagram of the MEMS device according to an embodiment of the present application.

FIG. 3 is a schematic diagram of a main process flow of a preparation method for a MEMS device according to an embodiment of the present application.

FIGS. 4a to 4k are schematic structural diagrams of the MEMS device after each step of the preparation method has been completed according to an embodiment of the present application.

### DETAILED DESCRIPTION OF THE EMBODIMENTS

The present application will be described in further detail with reference to the accompanying drawings and embodiments.

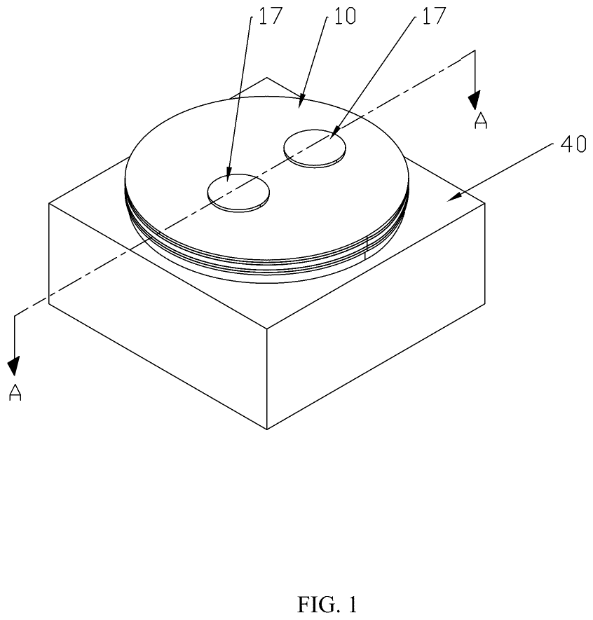

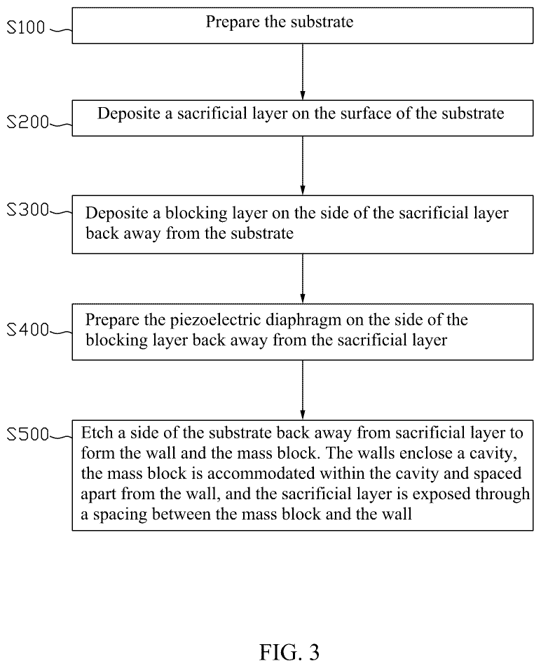

As shown in FIGS. 1, 3 and 4a to 4k, the present embodiment provides a MEMS device including a piezoelectric diaphragm 10, a blocking layer 20 disposed on a side of the piezoelectric diaphragm 10, a sacrificial layer 30 connected to a side of the blocking layer 20 back away from the piezoelectric diaphragm 10, and a substrate 40 connected to a side of the sacrificial layer 30 back away from the blocking layer 20. The substrate 40 includes a wall 41 connected to the side of the sacrificial layer 30 back away from the blocking layer 20, with the wall 41 forming a cavity 40a. The substrate 40 further includes a mass block 42 disposed on the side of the sacrificial layer 30 back away from the blocking layer 20 and accommodated within the cavity 40a, which is formed by etching the substrate 40 and spaced apart from the wall 41.

In this embodiment, the mass block 42 of the MEMS device is a part of the substrate 40, which is formed by etching the substrate 40 and is accommodated within the cavity 40a formed by the substrate 40. It is necessary to deposit and prepare the mass block 42 on the substrate 40 to free the thickness of the mass block 42 from the constraints of deposition techniques, thereby allowing the size of the mass block 42 to meet the requirements of bone conduction microphones and MEMS accelerometers.

After capturing vibration signals, the mass block 42 drives the piezoelectric diaphragm 10 to produce significant mechanical deformation. The piezoelectric diaphragm 10 converts vibration signals into voltage signals based on the piezoelectric effect. The design of the mass block 42 and the piezoelectric diaphragm 10 optimizes the sensitivity and response characteristics of the MEMS device, enabling it to achieve excellent acoustic and mechanical performance in applications such as bone conduction microphones or MEMS accelerometers.

The blocking layer 20 in the MEMS device has electrical insulation properties. The blocking layer 20 is configured to isolate the piezoelectric diaphragm 10 from the substrate 40, reducing electrical interference on the piezoelectric diaphragm 10 and maintaining the stability and reliability of the MEMS device. In this embodiment, the blocking layer 20 is formed by depositing polysilicon on the surface of the sacrificial layer 30.

The sacrificial layer 30 in the MEMS device serves as a support structure to hold the piezoelectric diaphragm 10 on one side of the substrate 40. Additionally, the sacrificial layer 30 has electrical insulation properties, creating an insulating barrier between the substrate 40 and the piezoelectric diaphragm 10.

In an embodiment, the wall 41 is ring-shaped, with its axis passing through the symmetrical center of the mass block 42, further enhancing the sensitivity and reliability of the MEMS device.

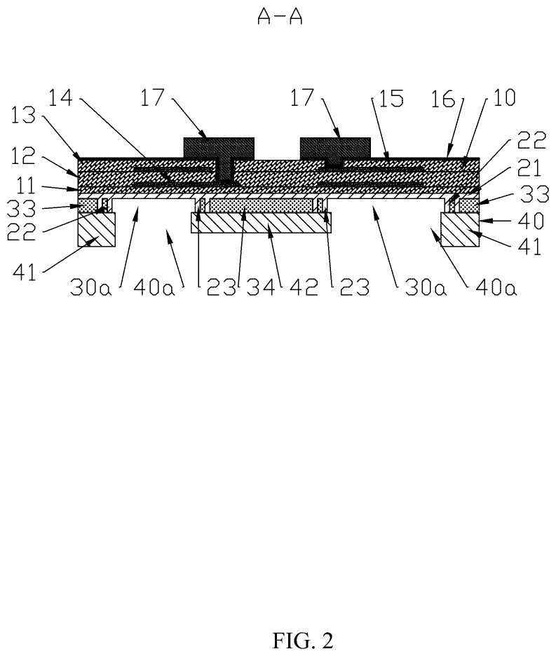

Furthermore, as shown in FIG. 2, the sacrificial layer 30 includes a first support portion 33 connecting the wall 41 and the blocking layer 20, and a second support portion 34 connecting the mass block 42 and the blocking layer 20. A gap 30a is provided between the first support portion 33 and the second support portion 34.

In this embodiment, the piezoelectric diaphragm 10 is elastic, and the gap 30a between the first support portion 33 and the second support portion 34 provides space for elastic deformation of the piezoelectric diaphragm 10, aiding in effectively transmitting solid vibrations to the piezoelectric diaphragm 10 and enhancing the sensitivity and response efficiency of the MEMS device in capturing vibration signals.

Furthermore, as shown in FIG. 2, the blocking layer 20 includes a main body 21 disposed between the piezoelectric diaphragm 10 and the sacrificial layer 30, as well as a first blocking wall 22 and a second blocking wall 23 extending from the main body 21 toward the substrate 40. The first blocking wall 22 is located within the gap 30a and covers the surface of the first support portion 33 facing the second support portion 34, while the second blocking wall 23 is located within the gap 30a and covers the surface of the second support portion 34 facing the first support portion 33.

The first blocking wall 22 and the second blocking wall 23 have electrical insulating properties. In an embodiment, the first blocking wall 22 and the second blocking wall 23 are both formed by depositing polysilicon. The first blocking wall 22 and the second blocking wall 23 are not corroded by chemical etchants. During the preparation of the MEMS device, the sacrificial layer 30 can be selectively etched to form the gap 30a between the first support portion 33 and the second support portion 34, thereby providing sufficient elastic deformation space for the piezoelectric diaphragm 10.

Furthermore, the sacrificial layer 30 and the blocking layer 20 are made of different materials. The blocking layer 20 may be made of polysilicon, while the sacrificial layer 30 may be made of silicon oxide. The different materials of the sacrificial layer 30 and the blocking layer 20 prevent the piezoelectric diaphragm from being damaged during the etching of the sacrificial layer.

In an embodiment, the first blocking wall 22, the second blocking wall 23, and the blocking layer 20 are formed by depositing the same material. The first blocking wall 22, the second blocking wall 23, and the blocking layer 20 are all formed by depositing polysilicon, while the sacrificial layer 30 is formed by depositing silicon oxide. This configuration facilitates selective etching of the sacrificial layer 30 during MEMS device preparation, thereby increasing the deformation space of the piezoelectric diaphragm 10. By eliminating the need for additional fabrication of the mass block 42 on the substrate 40, the mass block 42 formed by the substrate 40 etching can still effectively drive the piezoelectric diaphragm 10 to produce significant mechanical deformation after capturing and amplifying vibration signals.

Furthermore, the piezoelectric diaphragm 10 includes a fixing portion supported and fixed to the wall 41, and a plurality of cantilever portions extending from the fixing portion toward an upper portion of the cavity and suspending the mass block 42 within the cavity 40a. The plurality of cantilever portions are spaced apart from each other or connected together as a single unit. Along the thickness direction of the piezoelectric diaphragm 10, the portion of the projection of the piezoelectric diaphragm 10 onto the substrate 40 that falls within the wall 41 of the substrate 40 constitutes the fixing portion of the piezoelectric diaphragm 10, and the portion of the projection of the piezoelectric diaphragm 10 onto the substrate 40 that falls within the cavity 40a and the mass block 42 constitutes the cantilever portions. In some embodiments, the cantilevers are spaced apart, with one end of each cantilever connected to the first support section 33 and the other end connected to the second support section 34. Each cantilever of the piezoelectric diaphragm 10 may be connected to the mass block 42 through the second support section 34. When the mass block 42 captures the vibration signal and transmits it to the cantilever, the cantilever bends or deforms. The cantilevers convert the mechanical deformation into an electrical signal based on the piezoelectric effect. In other embodiments, a plurality of cantilevers are integrally connected and have elasticity. The periphery of the cantilevers is connected to the fixing portion, and the cantilevers are connected to the mass block 42 through the second support portion 34.

Furthermore, as shown in FIG. 2, the thickness direction of the wall 41, the thickness direction of the mass block 42, and the thickness direction of the substrate 40 are the same, and the thickness of the wall 41 is greater than the thickness of the mass block 42.

Furthermore, as shown in FIG. 2, the piezoelectric diaphragm 10 includes a plurality of piezoelectric layers stacked on the side of the blocking layer 20 back away from the substrate 40, a first electrode 14 disposed between any two adjacent piezoelectric layers, a second electrode 15 disposed between any two adjacent piezoelectric layers, a first lead-out electrode 16 extending from the first electrode 14 and second electrode 15 to the outer surface of the piezoelectric layer on a side of the blocking layer 20 back away from the substrate 40, and second lead-out electrodes 17 disposed on a surface of the first lead-out electrode 16.

In this embodiment, specifically, the plurality of the piezoelectric layers stacked on the side of the blocking layer 20 away from the substrate 40 are sequentially the first piezoelectric layer 11, the second piezoelectric layer 12, and the third piezoelectric layer 13. The first electrode 14 is disposed between the first piezoelectric layer 11 and the second piezoelectric layer 12, and the second electrode 15 is disposed between the second piezoelectric layer 12 and the third piezoelectric layer 13.

In some embodiments, the first electrode 14 and the second electrode 15 are made of Mo, the first lead-out electrode 16 is made of Ti, the second lead-out electrodes 17 are made of Al, and the piezoelectric layers are made of AlN.

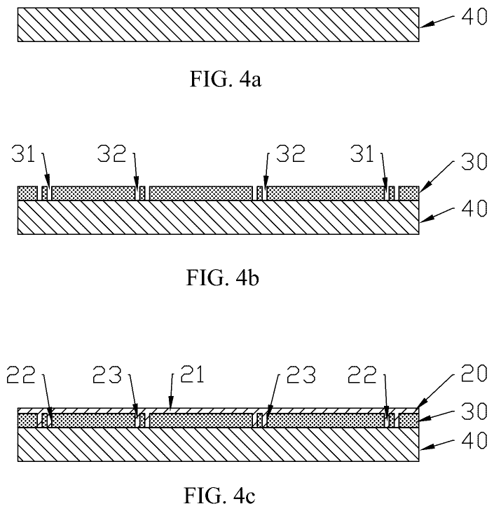

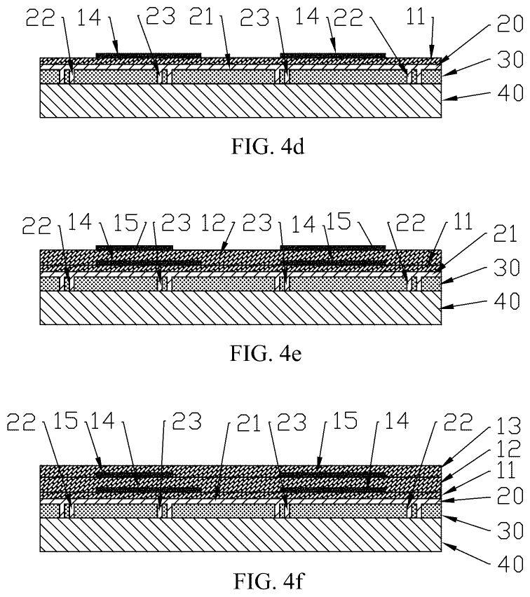

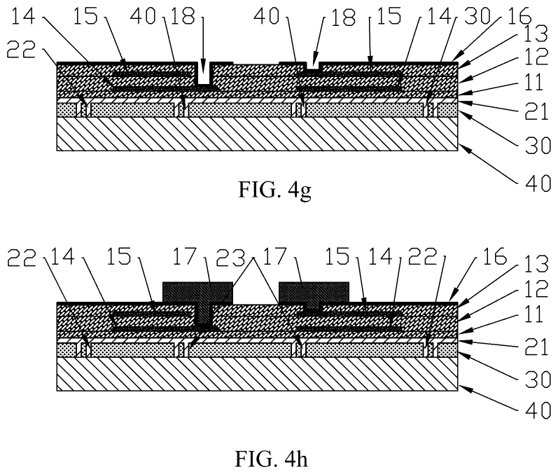

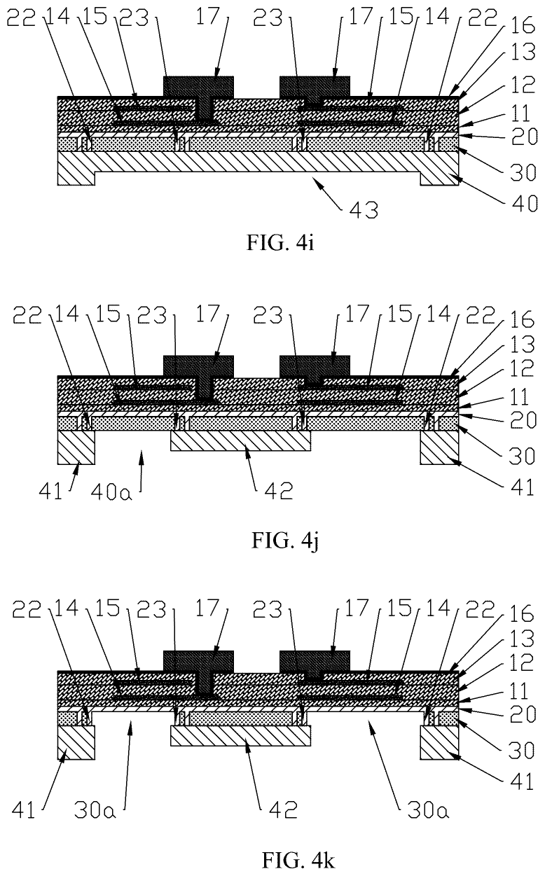

Furthermore, in this embodiment, as shown in FIGS. 4a to 4k. The preparation method for a MEMS device as described above includes the following steps:
S100: preparing the substrate 40;
S200, depositing a sacrificial layer 30 on the surface of the substrate 40;
S300, depositing a blocking layer 20 on the side of the sacrificial layer 30 back away from the substrate 40;
S400, preparing the piezoelectric diaphragm 10 on the side of the blocking layer 20 back away from the sacrificial layer 30;
S500: etching a side of the substrate 40 back away from the sacrificial layer 30 to form the wall 41 and the mass block 42. The walls 41 enclose a cavity 40a, the mass block 42 is accommodated within the cavity 40a and spaced apart from the wall 41, and the sacrificial layer 30 is exposed through a spacing between the mass block 42 and the wall 41.

In this embodiment, the wall 41 and the mass block 42 embedded within the wall 41 are formed by etching the substrate 40, eliminating the need for additional deposition on the substrate 40 to form the mass block 42, thereby freeing the size of the mass block 42 from the constraints of deposition techniques. The MEMS devices prepared using this method have the mass block 42 whose sizes meet the requirements of bone conduction microphones and MEMS accelerometers, offering improved sensitivity and vibration response characteristics, and achieving excellent acoustic and mechanical performance. Furthermore, compared to the conventional deposition process for forming the mass block 42, etching the substrate 40 to form the mass block 42 reduces the complexity of the MEMS device fabrication process and optimizes the MEMS device preparation.

As shown in FIG. 4b, furthermore, the step S200 includes:
S210: depositing the sacrificial layer 30 on the surface of the first side of the substrate 40.

In an embodiment, in step S210, silicon dioxide is deposited on the surface of the first side of the substrate 40 to form the sacrificial layer 30.

after step S210, the method further includes the following steps:
S220, etching the sacrificial layer 30 to form a first channel 31 and at least one second channel 32 that are arranged through the sacrificial layer 30 along the thickness direction. The first channel 31 and the second channels 32 are both annular in shape, and the first channel 31 is arranged around the second channels 32.

As shown in FIG. 4c, the step S300 specifically includes:
Depositing polysilicon on the surface of the sacrificial layer 30 back away from the substrate 40 to form the main body of the blocking layer 21, and depositing polysilicon within the first channel 31 and the second channels 32 to form the first blocking wall 22 and the second blocking wall 23, respectively.

In this embodiment, the blocking layer 20, the first blocking wall 22, and the second blocking wall 23 formed by depositing polysilicon on the sacrificial layer 30 are not corroded by the chemical etchant, and their function is to enable the sacrificial layer 30 to be selectively etched.

In this embodiment, in step S220, when etching the sacrificial layer 30, a plurality of annular channels that are arranged through the sacrificial layer 30 along the thickness direction may also be formed. A portion of the annular channels are arranged around the outer side of the first channel 31, and another portion of the annular channels are arranged around the inner side of the second channel 32.

Furthermore, step S310 further includes: depositing polysilicon in the grooves to form corresponding blocking walls.

It should be understood that in step S300, polysilicon may be deposited on the first channel 31, the second channel 32, and the side of the sacrificial layer 30 back away from the substrate 40, forming the first blocking wall 22, the second blocking wall 23, and the blocking layer 20 in a single deposition. Alternatively, polysilicon may first be deposited within the first channel 31 and second channel 32, followed by deposition of polysilicon on the side of the first blocking wall 22, second blocking wall 23, and sacrificial layer 30 back away from the substrate 40 to form the blocking layer 20.

As shown in FIGS. 4i to 4j, furthermore, the step S500 specifically includes:
Etching the side of the substrate 40 back away from the sacrificial layer 30 to form a through-hole in a region of the substrate 40 between the first blocking wall 22 and the second blocking wall 23, exposing the sacrificial layer 30 through the through-hole. The through-hole forms the spacing between the wall 41 and the mass block 42.

In this embodiment, the groove 43 is formed by etching the side of the substrate 40 away from the sacrificial layer 30. Along the thickness direction of the substrate 40, the projected outer periphery of the groove 43 is located between the first blocking wall 22 and the second blocking wall 23. Subsequently, the substrate 40 is etched to expose the sacrificial layer 30. The substrate 40 is formed into the wall 41 and the mass block 42 through a two-step etching process, such that the thickness of the wall 41 is greater than the thickness of the mass block 42.

As shown in FIG. 4k, further, after step 500, the process further includes:
Step 600: etching the sacrificial layer 30 to remove the sacrificial layer 30 exposed between the first blocking wall 22 and the second blocking wall 23, thereby forming a gap 30a within the sacrificial layer 30.

The sacrificial layer 30 is etched in a Boe solution to remove the silicon dioxide material between the first blocking wall 22, the second blocking wall 23, and the blocking layer 20.

As shown in FIGS. 4d to 4h, furthermore, the step S400 specifically includes:
As shown in FIG. 4d, step S410: depositing piezoelectric material on the side of the blocking layer 20 back away from the substrate 40 to form a first piezoelectric layer 11;
Depositing the first electrode 14 material on the side of the first piezoelectric layer 11 back away from the substrate 40 and patterning it to form the first electrode 14;
As shown in FIG. 4e, step S420: depositing piezoelectric material on the side of the first electrode 14 back away from the first piezoelectric layer 11 to form the second piezoelectric layer 12;
Depositing the first electrode material on the side of the second piezoelectric layer 12 back away from the substrate 40 and patterning it to form the second electrode 15;
As shown in FIG. 4f, step S430: depositing piezoelectric material on the side of the second electrode 15 back away from the second piezoelectric layer 12 to form the third piezoelectric layer 13;
As shown in FIGS. 4g and 4h, step S440: etching the second piezoelectric layer 12 and/or the third piezoelectric layer 13 to form electrode holes 18, and depositing conductive material in the electrode holes to connect the first electrode 14 and the second electrode 15 to the surface of the third piezoelectric layer 13 back away from the substrate 40.

Specifically, the step S440 includes:
As shown in FIG. 4g, step S441: providing electrode holes 18 on the second piezoelectric layer 12 and the third piezoelectric layer 13 at positions corresponding to the first electrode 14 and the second electrode 15, and depositing second electrode material on a side back away from the third piezoelectric layer 13, such that the second electrode material covers at least the surfaces of the first opening 18 and second opening 19, forming the first lead-out electrode 16;
As shown in FIG. 4h, step S442: depositing third electrode material on a surface of a region where the first lead-out electrode 16 covers the electrode hole 18, forming a second lead-out electrode 17, such that the first electrode 14 and the second electrode 15 are led out to the surface of the third piezoelectric layer 13 on the side away from the substrate 40.

In this embodiment, the piezoelectric material is AlN, the first electrode material is Mo, the second electrode material is Ti, and the third electrode material is Al. The first piezoelectric layer 11, the second piezoelectric layer 12, the third piezoelectric layer 13, the first electrode 14, and the second electrode 15 form a stacked piezoelectric diaphragm 10, which can convert vibration signals into electrical signals based on the piezoelectric effect.

It should be noted that, for the aforementioned method embodiments, for the sake of simplicity, they are all described as a series of action combinations. However, those skilled in the art should be aware that the present application is not limited to the described sequence of actions, as certain steps may be performed in other sequences or simultaneously according to the present application. Furthermore, those skilled in the art should also be aware that the embodiments described in the specification are preferred embodiments, and the actions and modules involved are not necessarily all required by this application.

In the above embodiments, the descriptions of each embodiment focus on different aspects, and parts not detailed in a particular embodiment may be referenced in the relevant descriptions of other embodiments.

Described above are only embodiments of the present application, and it should be pointed out that, for the ordinary technical personnel in the field, improvements may also be made without departing from the premise of the concept of the present application, but these are all within the protection scope of the present application.

What is claimed is:

1. A MEMS device, comprising:
a piezoelectric diaphragm;
a blocking layer disposed on a side of the piezoelectric diaphragm;
a sacrificial layer connected to a side of the blocking layer back away from the piezoelectric diaphragm; and
a substrate connected to a side of the sacrificial layer back away from the blocking layer, and comprising:
a wall connected to a side of the sacrificial layer back away from the blocking layer, with the wall forming a cavity; and
a mass block disposed on the side of the sacrificial layer back away from the blocking layer and accommodated within the cavity, the mass block being formed by etching the substrate and being spaced apart from the wall.

2. The MEMS device of claim 1, wherein the sacrificial layer comprises a first support portion connecting the wall and the blocking layer, and a second support portion connecting the mass block and the blocking layer, with a gap between the first support portion and the second support portion.

3. The MEMS device of claim 2, wherein the blocking layer comprises a main body disposed between the piezoelectric diaphragm and the sacrificial layer, and a first blocking wall and a second blocking wall extending from the main body toward the substrate; the first blocking wall is located within the gap and covers a surface of the first support member facing the second support member, and the second blocking wall is located within the gap and covers a surface of the second support member facing the first support member.

4. The MEMS device of claim 1, wherein the sacrificial layer and the blocking layer are made of different materials.

5. The MEMS device of claim 1, wherein the piezoelectric diaphragm comprises a fixing portion fixed to the wall and a plurality of cantilever portions extending from the fixing portion toward an upper portion of the cavity and suspending the mass block within the cavity, wherein the plurality of cantilever portions are spaced apart from each other or the plurality of cantilever portions are connected together as a single unit.

6. A preparation method for the MEMS device of claim 1, comprising:
preparing the substrate;
depositing the sacrificial layer on a surface of the substrate, and depositing the blocking layer on a side of the sacrificial layer back away from the substrate;
preparing the piezoelectric diaphragm on a side of the blocking layer back away from the sacrificial layer; and
etching a side of the substrate back away from the sacrificial layer to form the wall and the mass block, wherein the wall encloses the cavity, the mass block is accommodated within the cavity and spaced apart from the wall, and the sacrificial layer is exposed through a spacing between the mass block and the wall.

7. The preparation method for the MEMS device of claim 6, wherein after depositing the sacrificial layer on the surface of the substrate, the method further comprises:
etching the sacrificial layer to form a first channel and a second channel that are arranged through the sacrificial layer along a thickness direction, wherein the first channel and the second channel are both annular in shape, and the first channel is arranged around an outer side of the second channel;
the step of depositing the blocking layer on the side of the sacrificial layer back away from the substrate comprises:
depositing polysilicon on the surface of the sacrificial layer back away from the substrate to form a main body of the blocking layer, and depositing polysilicon within the first channel and the second channel to form a first blocking wall and a second blocking wall, respectively.

8. The preparation method for the MEMS device of claim 7, wherein the step of etching the side of the substrate back away from the sacrificial layer to form the wall and the mass block comprises:
etching the side of the substrate back away from the sacrificial layer to form a through-hole in a region of the substrate corresponding to the first blocking wall and the second blocking wall, exposing the sacrificial layer through the through-hole, wherein the through-hole forms the spacing between the wall and the mass block.

9. The preparation method for the MEMS device of claim 8, wherein after etching the side of the substrate back away from the sacrificial layer to form the wall and the mass block, the method further comprises:
etching the sacrificial layer to remove the sacrificial layer exposed through the through-hole between the first blocking wall and the second blocking wall, thereby forming a gap within the sacrificial layer.

10. The preparation method for the MEMS device of claim 6, wherein the step of preparing the piezoelectric diaphragm on the side of the blocking layer back away from the sacrificial layer comprises:
depositing piezoelectric material on the side of the blocking layer away from the substrate to form a first piezoelectric layer;
depositing a first electrode material on a side of the first piezoelectric layer back away from the substrate and patterning it to form a first electrode;
depositing piezoelectric material on a side of the first electrode back away from the first piezoelectric layer to form a second piezoelectric layer;
depositing a first electrode material on a side of the second piezoelectric layer back away from the substrate and patterning it to form a second electrode;
depositing piezoelectric material on the side of the second electrode back away from the second piezoelectric layer to form a third piezoelectric layer; and
etching the second piezoelectric layer and/or the third piezoelectric layer to form an electrode hole, and depositing conductive material within the electrode hole to connect the first electrode and the second electrode to a surface of the third piezoelectric layer back away from the substrate.
